(19) United States
(12) Patent Application Publication
(10) Pub. No.: US 2002/0044076 A1
(43) Pub. Date: Apr. 18, 2002

(54) Current-steering D/A converter and unit cell

(76) Inventors: Chi-Tai Yao, Kaohsiung Hsien (TW); Wei-Chen Shen, Hsinchu (TW); Hung Chih Liu, Hsinchu (TW)

Correspondence Address: Michael P. Dunnam, Esq., WOODCOCK WASHBURN KURTZ, MACKIEWICZ & NORRIS LLP, One Liberty Place - 46th Floor, Philadelphia, PA, 19103, US

(21) Appl. No.: 09/749,976

(22) Filed: Dec. 28, 2000

(30) Foreign Application Priority Data
Aug. 30, 2000 (TW) 89117611

(51) Int. Cl. H03M 1/66

(52) U.S. Cl. 341/136; 341/144; 341/153

(57) ABSTRACT

The present invention discloses a current-steering digital-to-analog converter and unit cells. The present invention proposes an n-well bias control circuit for generating a bias voltage whose magnitude is less than the power voltage, therefore the body effect of the transistors could be reduced. Relatively, the threshold voltage and V_{GS} would be reduced. Therefore, even in a low-voltage operation, each transistor could be operated normally in the saturation region. Besides, the plurality of pairs of current switches could be implemented in the same n-well region, instead of being implemented in different n-well regions with leaving a space among each other. Finally, the chip area would be reduced.

### BACKGROUND OF THE INVENTION

1. Field of the Invention

The present invention relates to a current-steering D/A converter and unit cell, and particularly to a current-steering D/A converter and unit cell which can operate at low voltages and occupy less areas.

2. Description of Related Art

A current-steering D/A converter is usually used in signal processing. For example, a graphic chip uses three current-steering D/A converters to transform red, blue and green digital video signals to analog video signals.

FIG. 1 shows a prior art current-steering D/A converter. The currentsteering D/A converter 10 comprises a current reference generating module 11, a controllable current switching module 12 and a current-to-voltage converting module 13. The current reference generating module 11 utilizes the characteristic of virtual short of an operational amplifier 14 to transfer a positive-end voltage V_{ref} to a negative end. Relatively, the current Iref flowing through a resistor 17 is equal to V_{ref}/R_{ref}. A transistor 18 serves as a diode, therefore a bias voltage BIA1 could be achieved, and the current flowing through the transistor 18 is equal to I_{ref}. The controllable current switching module 12 comprises a plurality of transistors 15 and a current switching matrix 16. The plurality of transistors 15 could use the bias voltage BIA1 to generate I_{ref} by current mirroring. The current switching matrix 16 receives and decodes input digital codes of the current-steering D/A converter 10, and generates a proportional current 10. The current-to-voltage generating module 13 utilizes an operational amplifier 19 to transform the current I_{O} into an analog output voltage V_{O}.

In FIG. 2, a plurality of transistors 15 and current switching matrix 16 are rearranged inside the controllable current switching matrix 12 to form a plurality of unit cells 21, and an output current I_{O} is accumulated from the plurality of unit cells 21.

FIGS. 3(a) to 3(c) show a structural diagram of a prior art current-steering D/A converter. The structure in FIG. 3(a) comprises first to fourth transistors 31˜34, wherein the third and fourth transistors form a differential pair, and the first and the second transistors forms a cascode-connected current source for increasing the output impedance of current sources. In the structure, the n-well regions of all transistors are electrically connected to a power source. Therefore for the second to the fourth transistors 32˜34, an excessively large threshold voltage will be created due to body effect. Equation (1) is a well-known formula for calculating a threshold voltage of MOS transistors.

Vₜₕ=Vₜₕ₀+γ(\sqrt{2Ψ_{F}+V_{BS}}−\sqrt{2Ψ_{F}}) (1)

Wherein Vₜₕ represents threshold voltage, Vₜₕ₀ represents threshold voltage when V_{BS} (voltage difference between a body terminal and a source terminal) is equal to zero, γ and Ψ_{F} are constants of body bias effect. It can be from equation (1) that body effect is positively proportional to a value of V_{BS}, and causes the increase in the threshold voltage Vₜₕ of the transistors 32˜34. The structure in FIG. 3(a) is not suitable for operating at low power voltages, and will cause the first to the fourth transistors 31˜34 not to work in the saturation region. The structure in FIG. 3(b) is similar to that in FIG. 3(a), and the only difference resides in using the first transistor 31 as cascode-connected transistor. Likewise, the structure in FIG. 3(b) is not suitable for operating at low power voltages.

In the structure shown in FIG. 3(c), the n-well regions of the third and the fourth transistors 33 and 34 are connected to the source terminals for eliminating the body effect by forcing V_{BS} to be zero. Although this method is more convenient than the prior art technologies, but creates a disadvantage of occupying a large layout area.

FIG. 4 shows a floorplanning diagram of a current-steering D/A converter in FIG. 3. If the above transistors are of PMOS type, a lot of n-well regions should be separated in manufacturing process. The plurality of first and second transistors 31 and 32 could be implemented in the same n-well region 41, each of third and fourth transistors 33 and 34 could be implemented in the same n-well region, and a d-width space is kept between two n-well regions. According to the design rule of PMOS, a minimal space should be kept between two n-well regions. For example, in a 0.18 μm manufacturing process, the minimal width of the space between two n-well regions is 10 μm. For an 8-bit digital-to-analog converter, 255 d-width gaps between two n-well regions are formed. It is obvious that the structure in FIG. 3(c) will waste a lot of chip area.

Recently, it is a trend that a lot of electronic products are operated at low voltages, therefore a current-steering D/A converter and unit cell suitable for a low voltage operation are desired.

### SUMMARY OF THE INVENTION

The first object of the present invention is to propose a current-steering D/A unit cell suitable to a low-voltage operation.

The second object of the present invention is to propose a current-steering D/A unit cell for reducing chip area.

For achieving the above objects, the present invention proposes an n-well bias control circuit for generating a bias voltage whose magnitude is less than the power voltage; therefore the body effect of the transistors could be reduced (relatively, the threshold voltage and V_{GS} would be reduced). Therefore, even in a low-voltage operation, each transistor could be operated normally in the saturation region. Besides, the plurality of pairs of current switches could be implemented in the same n-well region, instead of being implemented in different n-well regions with leaving a space among each other. Finally, the chip area would be reduced.

The first embodiment of the current-steering D/A unit cell according to the present invention comprises at least one cascode-connected transistor and a pair of current switches. The n-well region of said at least one cascode-connected transistor is electrically connected to a power source. The source terminals of said pair of current switches are electrically connected to the drain terminal of one of said at least one cascode-connected transistor, the n-well regions of said pair of current switches are electrically connected to a second bias voltage outputted from an external bias circuit and the gate terminals of said pair of current switches are controlled by decoded input digital codes.

The second embodiment of the current-steering D/A unit cell according to the present invention comprises at least one cascode-connected transistor and a pair of current switch. The n-well region of said at least one cascode-connected transistor is electrically connected to a power source except a second transistor. The source terminals of said pair of current switches are electrically connected to the drain terminal of the second transistor, the n-well regions of said pair of current switches and the second transistor are electrically connected to a second bias voltage outputted from an external bias circuit, and the gate terminals of said pair of current switches are controlled by decoded input digital codes.

By the above connection, the magnitude of the current outputted from the drain terminals of said pair of current switches is proportional to a value of said exterior input digital codes.

The bias circuit comprises a n-well bias replica circuit, a buffer and at least one capacitor. The n-well bias replica circuit is used to generate a first bias voltage VBW0. The buffer is connected to the n-well bias replica circuit for increasing the driving capability of said first bias voltage VBW0 and generating the second bias voltage VBW. The capacitor is connected to the output of the buffer for stabilizing the second bias voltage.

The third object of the present invention is to propose a current-steering D/A converter suitable to a low voltage operation.

The fourth object of the present invention is to propose a current-steering D/A converter for reducing chip area.

For achieving the third and the fourth objects, the present invention proposes a current-steering D/A converter, which comprises a controllable current switches module, a current reference generating module and a bias circuit. The controllable current switches module includes a plurality of current-steering digital-to-analog unit cells. The current reference generating module is used to generate bias voltage of said cascode-connected transistor. The bias circuit is used to generate said second bias voltage.

### BRIEF DESCRIPTION OF THE DRAWINGS

The present invention will be described according to the appended drawings in which:

FIG. 1 shows a prior art current-steering D/A converter;

FIG. 2 shows a schematic diagram of a rearranged controllable current switches module in FIG. 1;

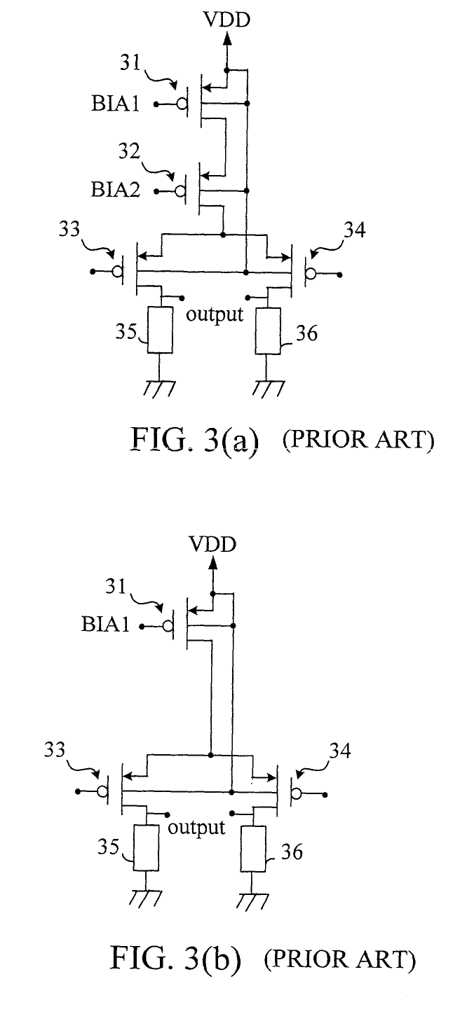

FIGS. 3(a) to 3(c) show a structural diagram of a prior art currentsteering D/A converter;

FIG. 4 shows a floorplanning diagram of a current-steering D/A converter in FIG. 3;

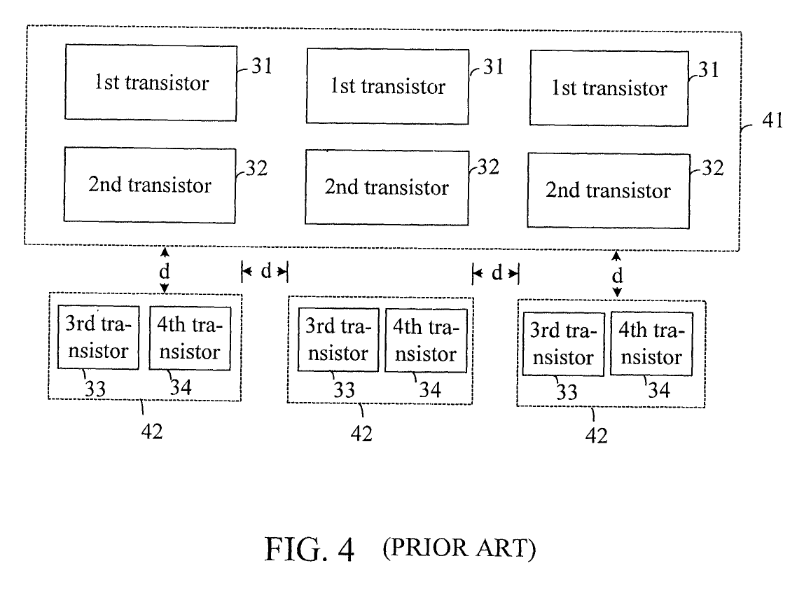

FIG. 5 shows a schematic diagram of a controllable current switches module of a current-steering DIA converter according to the present invention;

FIGS. 6(a) to 6(d) show schematic diagrams of current-steering D/A unit cells according to the present invention;

FIG. 7 shows a schematic diagram of an n-well bias circuit according to the present invention;

FIG. 8 shows a unit cell of a n-well bias replica circuit; and

FIG. 9 shows a floorplanning diagram of a current-steering D/A unit cell according to the present invention.

### PREFERRED EMBODIMENT OF THE PRESENT INVENTION

The present invention does not limited restrict to any kind of transistors, but is most suitable to PMOS transistors. Therefore, PMOS transistors are taken as an example in the following embodiments.

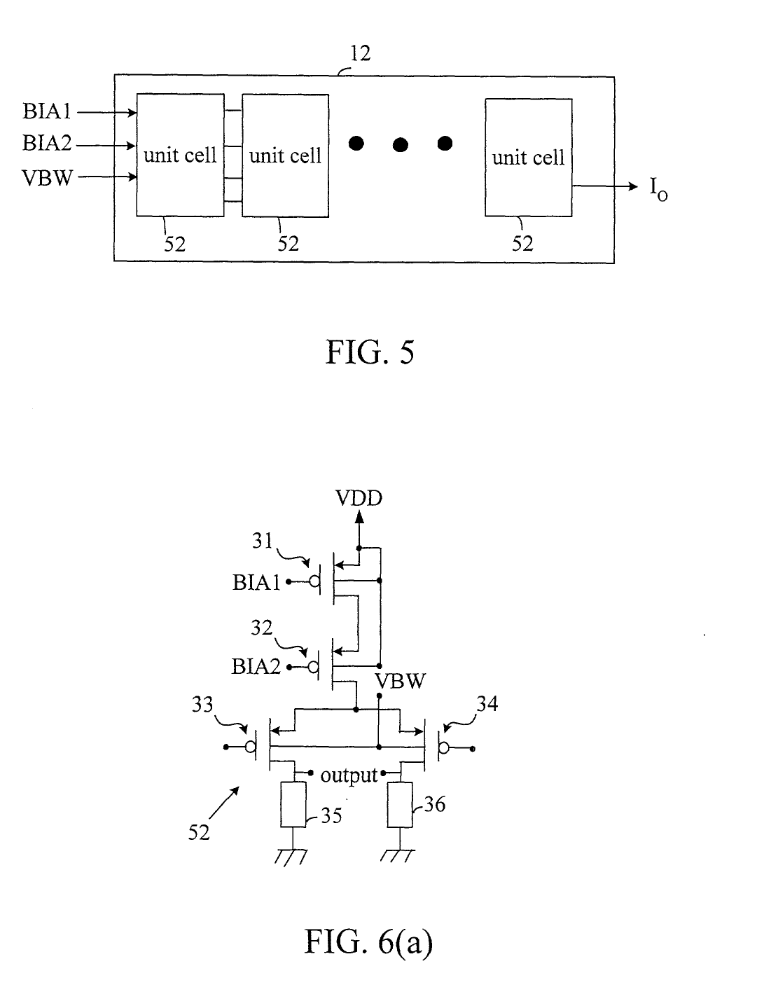

FIG. 5 shows a schematic diagram of a controllable current switches module of a current-steering D/A converter according to the present invention. The controllable current switches module 12 of the present invention comprises a plurality of unit cells 52, which receives bias voltages BIA1 and BIA2 (provided that there are two cascode-connected transistors, and the number of bias voltage is proportional to the number of cascode-connected transistors) generated by the current reference generating module 11 and a second bias voltage VBW for independently controlling the n-well region, and the plurality of unit cells accumulates their respective output currents as I_{O}.

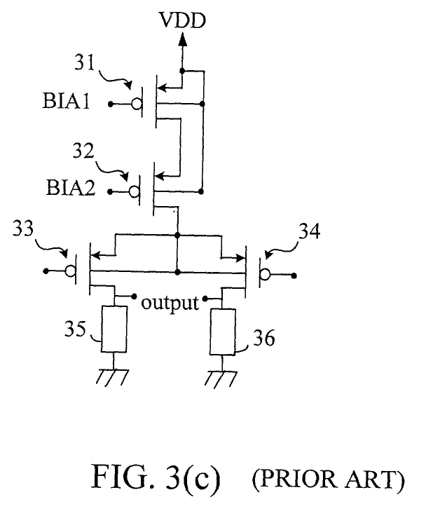

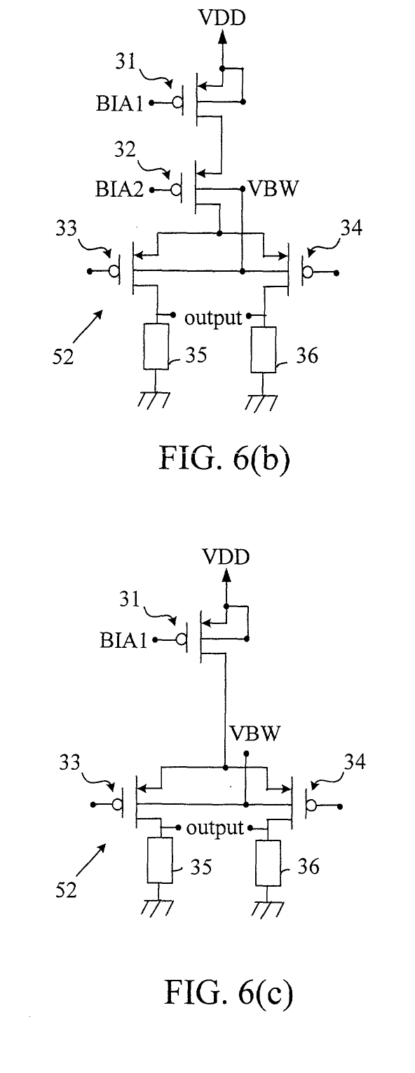

FIGS. 6(a) to 6(d) show schematic diagrams of current-steering D/A unit cells according to the present invention. In FIG. 6(a), the first and the second transistors 31 and 32 are used to form a bias load, and third and fourth transistors 33 and 34 are used to form a pair of current switches and are grounded through loads 35 and 36. The difference from the prior art structure in FIG. 3(a) is that in FIG. 6(a), the n-well regions of the third and fourth transistors 33 and 34 are not connected to a power source, but electrically connected to a second bias voltage VBW that is independently controlled. The magnitude of the second bias voltage VBW is less than that of the power source by well designing. Therefore, the body effect of the transistors 33 and 34 could be reduced. Relatively, the threshold voltage of the transistors 33 and 34 could also be reduced. The outputs of the structures in FIGS. 6(a) to 6(d) are a differential output, but could also be a single-ended output in different practical applications. The input ends of the pair of current switches 33 and 34 are controlled by decoded input digital codes to generate a proportional current output. The difference between the structure of the FIG. 6(b) and that of FIG. 6(a) is that the n-well bias of the second transistor 32 is FIG. 6(b) is controlled by the second bias voltage VBW, and the characteristic of the structure is to reduce the threshold voltage of the second transistor 32 and to increase the threshold voltage of the third and fourth transistors 33 and 34. The difference between the structure of FIG. 6(c) and that of FIG. 6(a) is that in FIG. 6(c), only one transistor, i.e. the transistor 31 constitutes current source and the present invention does not limit the number of cascode-connected transistors. The difference between the structure of FIG. 6(d) and that of FIG. 6(b) is that three transistors 31, 32 and 61 are cascode-connected, and the n-well region of the second transistor 32 is controlled by the second bias voltage VBW.

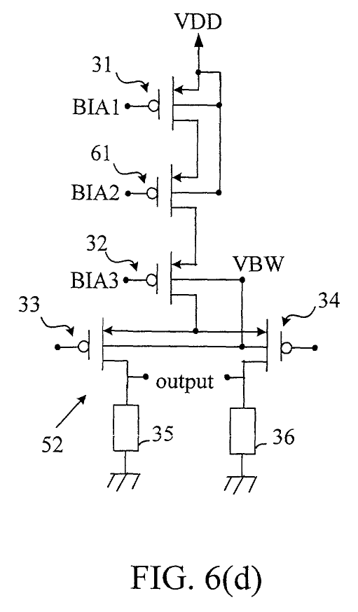

FIG. 7 shows a schematic diagram of an n-well bias circuit according to the present invention for generating the second bias voltage VBW of a plurality of transistors. First, the bias voltage BIA1 and BIA2 are generated by a well-known bias circuit, and then a first bias voltage VBW0 is generated by a n-well bias replica circuit 71. The first bias voltage VBW0 goes through a buffer 72 to generate the second bias voltage VBW. The buffer 72 works as a voltage follower for supplying high output impedance and strong driving capability. It should be noted that the second bias voltage VBW is connected to an on-chip capacitor 73 or an external capacitor 74 for stabilizing the output voltage, such as reducing the noise during voltage switching. The bias circuit of the present invention is not so complicated, and only a small area is occupied.

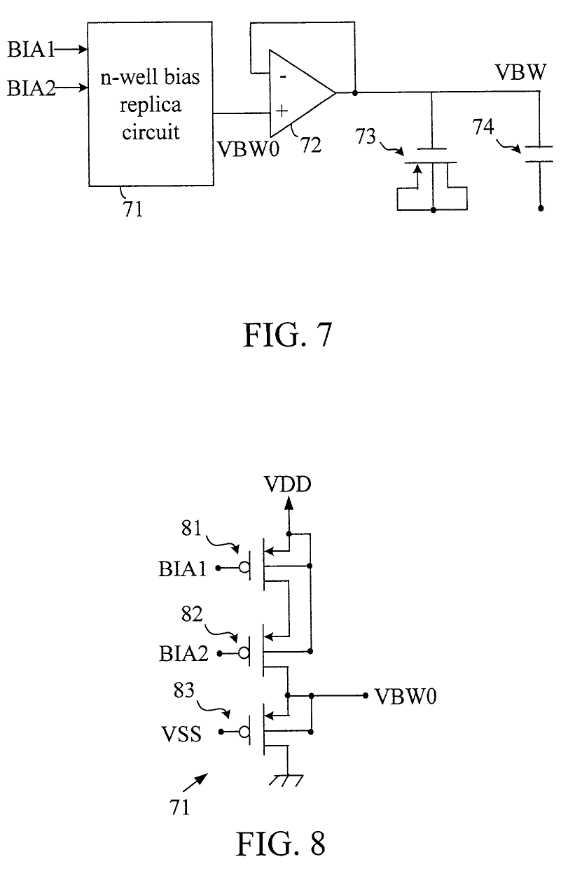

FIG. 8 shows a unit cell of an n-well bias replica circuit 71, which is formed by three transistors 81 to 83. The gate terminal of a sixth transistor 83 is electrically connected to ground VSS. The transistors 81 and 82 are used as cascode-connected transistors. In practical application, the number of the transistors in the cascode-connected transistors could be adjusted in accordance with different demands. Gate terminals of the transistors are electrically connected to bias voltage BIA1 and BIA2. The drain terminal of the sixth transistor 83 is electrically connected to the n-well region, and outputs a first bias voltage VBW0. The n-well bias replica circuit 71 could be duplicated by utilizing the three-transistor structure as a basic model.

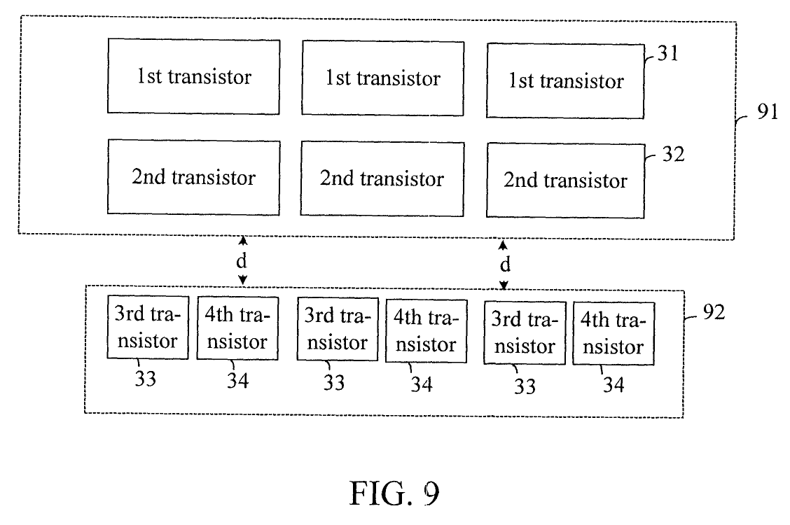

FIG. 9 shows a floorplanning diagram of a current-steering D/A unit cell according to the present invention, wherein a plurality of first and second transistors 31 and 32 can be implemented in the same n-well region 92, and a plurality of third and fourth transistors 33 and 34 can be implemented in the same n-well region 92. Since two neighboring pairs of current switches including the third and fourth transistors 33 and 34 do not have a d-width gap, the structure of the present invention will save more chip area.

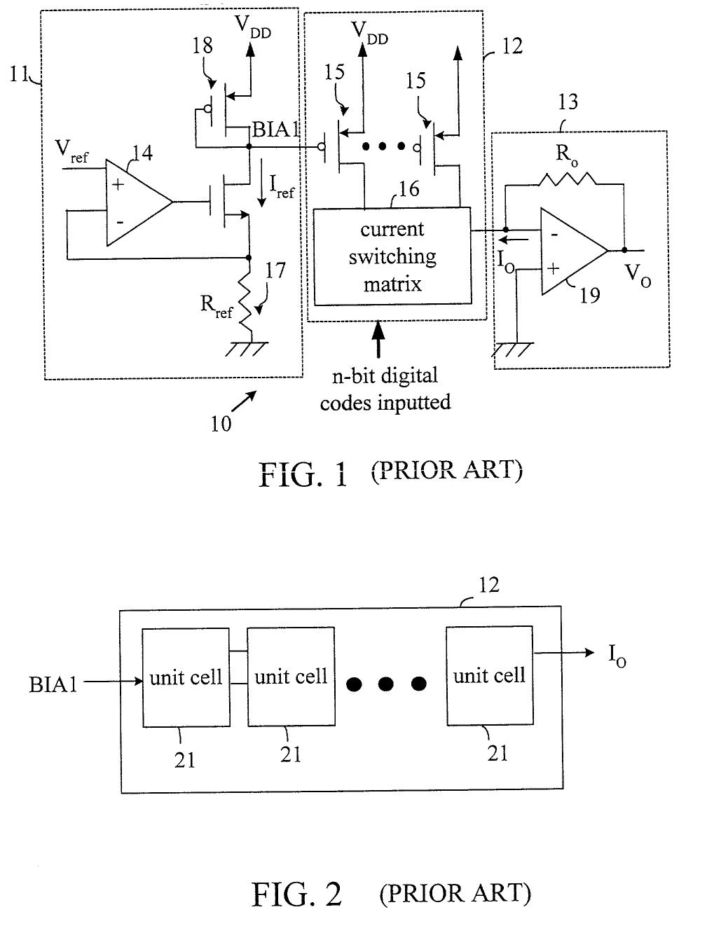

The current-steering digital-to-analog converter according to the present invention comprises a controllable current switches module 12 including the unit cell 52 mentioned above, a current reference generating module 11 and a current-to-voltage converting module 13. The structure of the current reference generating module 11 in FIG. 1 is one embodiment according to the present invention, the current reference generating module 11 is used to generate the bias voltage BIA of the cascode-connected transistors of the unit cell 52 or a reference current. The structure of the current-to-voltage converting module 13 is one embodiment according to the present invention, and another possible implementation is formed by a resistance matrix. The current-to-voltage converting module 13 is used to transform the output current I_{O} of the plurality of unit cells 52 into an output voltage.

The above-described embodiments of the present invention are intended to be illustrated only. Numerous alternative embodiments may be devised by those skilled in the art without departing from the scope of the following claims.

What is claimed is:

1. A current-steering digital-to-analog unit cell, comprising:
at least one cascode-connected transistor, the n-well region of said at least one cascode-connected transistor electrically connected to a power source; and
a pair of current switches, the source terminals of said pair of current switches electrically connected to the drain terminal of one of said at least one cascode-connected transistor, the n-well regions of said pair of current switches electrically connected to a second bias voltage outputted from an external bias circuit and the gate terminals of said pair of current switches controlled by decoded input digital codes;
whereby the magnitude of the current outputted from the drain terminal of said pair of current switches is proportional to a value of said decoded input digital codes.

2. The current-steering digital-to-analog unit cell of claim 1, wherein said bias circuit comprises:
an n-well bias replica circuit for generating a first bias voltage;
a buffer for increasing the driving capability of said first bias voltage and generating the second bias voltage; and
at least one capacitor connected to the output of said buffer for stabilizing the second bias voltage.

3. The current-steering digital-to-analog unit cell of claim 2, wherein said n-well bias replica circuit includes a plurality of unit cells, and each of said unit cells comprises:
at least one cascode-connected transistor, the n-well region of said at least one cascode-connected transistor electrically connected to a power source; and
a sixth transistor, the gate terminal and drain terminal of said sixth transistor electrically connected to ground, the source terminal of said sixth transistor electrically connected to the drain terminal of one of said at least one cascode-connected transistor, and the n-well region of said sixth transistor electrically connected to the source terminal and outputting said first bias voltage.

4. The current-steering digital-to-analog unit cell of claim 1, wherein the output of the drain terminals of said pair of current switches is designed as one of differential output and single-ended output.

5. A current-steering digital-to-analog unit cell, comprising:
at least one cascode-connected transistor, the n-well region of said at least one cascode-cornnected transistor electrically connected to a power source except a second transistor; and
a pair of current switches, the source terminals of said pair of current switches electrically connected to the drain terminal of the second transistor, the n-well regions of said pair of current switches and the second transistor electrically connected to a second bias voltage outputted from an external bias circuit, and the gate terminals of said pair of current switches controlled by decoded input digital codes;
whereby the magnitude of the current outputted from the drain terminals of said pair of current switches is proportional to a value of said decoded input digital codes.

6. The current-steering digital-to-analog unit cell of claim 5, wherein the bias circuit comprises:
an n-well bias replica circuit for generating a first bias voltage; a buffer for increasing the driving capability of said first bias voltage and generating the second bias voltage; and
at least one capacitor connected to the output of the buffer for stabilizing the second bias voltage.

7. The current-steering digital-to-analog unit cell of claim 6, wherein said n-well bias replica circuit includes a plurality of unit cells, and each of said unit cells comprises:
at least one cascode-connected transistor, the n-well region of said at least one cascode-connected transistor electrically connected to a power source; and
a sixth transistor, the gate terminal and drain terminal of said sixth transistor electrically connected to ground, the source terminal of said sixth transistor electrically connected to the drain terminal of one of said at least one cascode-connected transistor, and the n-well region of said sixth transistor electrically connected to the source terminal and outputting said first bias voltage.

8. The current-steering digital-to-analog unit cell of claim 5, wherein the output of the drain terminals of said pair of current switches is designed as one of differential output and single-ended output.

9. A current-steering digital-to-analog converter, comprising:
a controllable current switches module including a plurality of current-steering digital-to-analog unit cells, each of said unit cells including:
at least one cascode-connected transistor, the n-well region of said at least one cascode-connected transistor electrically connected to a power source; and
a pair of current switches, the source terminals of said pair of current switches electrically connected to the drain terminal of one of said at least one cascode-connected transistor, the n-well regions of said pair of current switches electrically connected to a second bias voltage outputted from a bias circuit, and the gate terminals of said pair of current switches controlled by decoded input digital codes, and the magnitude of the current outputted from the drain terminals is proportional to a value of said decoded input digital codes;
a current reference generating module for generating a bias voltage of said at least one cascode-connected transistor; and
a bias circuit for generating said second bias voltage.

10. The current-steering digital-to-analog converter of claim 9, wherein said bias circuit comprises:
an n-well bias replica circuit for generating a first bias voltage;
a buffer for increasing the driving capability of said first bias voltage and generating the second bias voltage; and
at least one capacitor connected to the output of said buffer for stabilizing the second bias voltage.

11. A current-steering digital-to-analog converter, comprising:
a controllable current switches module including a plurality of current-steering digital-to-analog unit cells, each of said unit cells including:
at least one cascode-connected transistor, the n-well regions of said at least one cascode-connected transistor electrically connected to a power source except a second transistor; and
a pair of current switches, the source terminals of said pair of current switches electrically connected to the drain terminal of said second transistor, the n-well regions of said pair of current switches and the second transistor electrically connected to a second bias voltage outputted from a bias circuit, and the gate terminals of said pair of current switches controlled by decoded input digital codes, and the magnitude of the current outputted from the drain terminal being proportional to a value of said decoded input digital codes;
a current reference generating module for generating a bias voltage of said cascode-connected transistor; and
a bias circuit for generating said second bias voltage.

12. The current-steering digital-to-analog converter of claim 11, wherein said bias circuit comprises:
an n-well bias replica circuit for generating a first bias voltage;
a buffer for increasing the driving capability of said first bias voltage and generating said second bias voltage; and
at least one capacitor connected to the output of the buffer for stabilizing said second bias voltage.
